(19) United States
(12) Patent Application Publication
(10) Pub. No.: US 2020/0083138 A1
(43) Pub. Date: Mar. 12, 2020

(54) Power Semiconductor Module Arrangement, Substrate Arrangement, and Method for Producing the Same

(71) Applicant: Infineon Technologies AG, Neubiberg (DE)

(72) Inventor: Olaf Hohlfeld, Warstein (DE)

(21) Appl. No.: 16/567,383

(22) Filed: Sep. 11, 2019

(30) Foreign Application Priority Data
Sep. 12, 2018 (EP) 18193912.5

(51) Int. Cl. H01L 23/373; H05K 7/20; H01L 23/367; H01L 21/48

(52) U.S. Cl. CPC H01L 23/3733; H05K 7/209; H01L 25/072; H01L 21/4882; H01L 23/367

(57) ABSTRACT

A power semiconductor module arrangement includes a heat sink, a substrate arrangement arranged on the heat sink in a vertical direction, a heat-conducting paste arranged between a surface of the substrate arrangement and a surface of the heat sink in the vertical direction, wherein a plurality of thermally conducting particles is evenly distributed within the heat-conducting paste, and a plurality of whiskers or fibers. Each of the plurality of whiskers or fibers has a first end and a second end. The first end of each of the plurality of whiskers or fibers is inseparably connected to either the surface of the substrate arrangement or to the surface of the heat sink.

### TECHNICAL FIELD

The instant disclosure relates to a power semiconductor module arrangement, a substrate arrangement, and a method for producing the same, in particular to a power semiconductor module arrangement comprising a heat sink.

### BACKGROUND

Power semiconductor module arrangements usually include at least one substrate. The substrate may be arranged on a base plate. However, power semiconductor module arrangements without a base plate are also known. A semiconductor arrangement including a plurality of controllable semiconductor components (e.g., two IGBTs in a half-bridge configuration) is usually arranged on at least one of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor components are mounted, for example, on the first metallization layer. The first metallization layer may be a structured layer while the second metallization layer is usually a continuous layer. The second metallization layer may be attached to a base plate.

Heat that is generated by the controllable semiconductor components is dissipated through the substrate to the base plate and/or to a heat sink. A heat-conducting paste is usually arranged between the substrate and the heat sink or between the base plate and the heat sink to effectively conduct the heat away from the substrate.

There is a need for an improved power semiconductor module arrangement and improved substrate arrangement which provide for a good thermal conductivity between the substrate or base plate and the heat sink.

### SUMMARY

A power semiconductor module arrangement includes a heat sink, a substrate arrangement arranged on the heat sink in a vertical direction, a heat-conducting paste arranged between a surface of the substrate arrangement and a surface of the heat sink in the vertical direction, wherein a plurality of thermally conducting particles is evenly distributed within the heat-conducting paste, and a plurality of whiskers or fibers. Each of the plurality of whiskers or fibers comprises a first end and a second end, and the first end of each of the plurality of whiskers or fibers is inseparably connected to either the surface of the substrate arrangement or to the surface of the heat sink.

A method for producing a power semiconductor module arrangement includes forming a plurality of whiskers or fibers on at least one of a surface of a heat sink and a surface of a substrate arrangement, applying a heat conducting paste to one of the surface of the substrate arrangement and the surface of the heat sink, thereby enclosing the plurality of whiskers or fibers arranged on the respective surface, wherein a plurality of thermally conducting particles is evenly distributed within the heat-conducting paste, and mounting the substrate arrangement to the heat sink with the heat conducting paste and the plurality of whiskers or fibers arranged between the surface of the substrate arrangement and the surface of the heat sink. Each of the plurality of whiskers or fibers comprises a first end and a second end, and the first end of each of the plurality of whiskers or fibers is inseparably connected to either the first surface of the substrate arrangement or to the surface of the heat sink

A semiconductor substrate includes a surface, a plurality of whiskers or fibers formed on the surface, and a heat-conducting paste arranged on the first surface of the substrate arrangement and enclosing the plurality of whiskers or fibers. A plurality of thermally conducting particles is evenly distributed within the heat-conducting paste, each of the plurality of whiskers or fibers comprises a first end and a second end, and the first end of each of the plurality of whiskers or fibers is inseparably connected to the surface of the substrate arrangement.

A method for producing a substrate arrangement includes forming a plurality of whiskers or fibers on a surface of the substrate arrangement, applying a heat conducting paste to the surface of the substrate arrangement, thereby enclosing the plurality of whiskers or fibers arranged on the surface, wherein a plurality of thermally conducting particles is evenly distributed within the heat-conducting paste. Each of the plurality of whiskers or fibers comprises a first end and a second end, and the first end of each of the plurality of whiskers or fibers is inseparably connected to the first surface of the substrate arrangement.

The invention may be better understood with reference to the following drawings and the description. The components in the figures are not necessarily to scale, emphasis is instead being placed upon illustrating the principles of the invention. Moreover, in the figures, like reference numerals designate corresponding parts throughout the different views.

### BRIEF DESCRIPTION OF THE DRAWINGS

FIG. 1 schematically illustrates a cross-sectional view of a semiconductor substrate arrangement without a base plate.

FIG. 2 schematically illustrates a cross-sectional view of a semiconductor substrate arrangement including a base plate.

FIG. 3 schematically illustrates a cross-sectional view of a section of the semiconductor substrate arrangement of FIG. 2.

FIG. 4 schematically illustrates a cross-sectional view of a section of the semiconductor substrate arrangement of FIG. 2 according to one example.

FIG. 5 schematically illustrates a cross-sectional view of a section of the semiconductor substrate arrangement of FIG. 2 according to another example.

FIGS. 6A to 6C schematically illustrate a method for producing a semiconductor substrate arrangement and a power semiconductor module arrangement according to one example.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. A semiconductor body as described herein may be made from (doped) semiconductor material and may be a semiconductor chip or be included in a semiconductor chip. A semiconductor body has electrically connecting pads and includes at least one semiconductor element with electrodes.

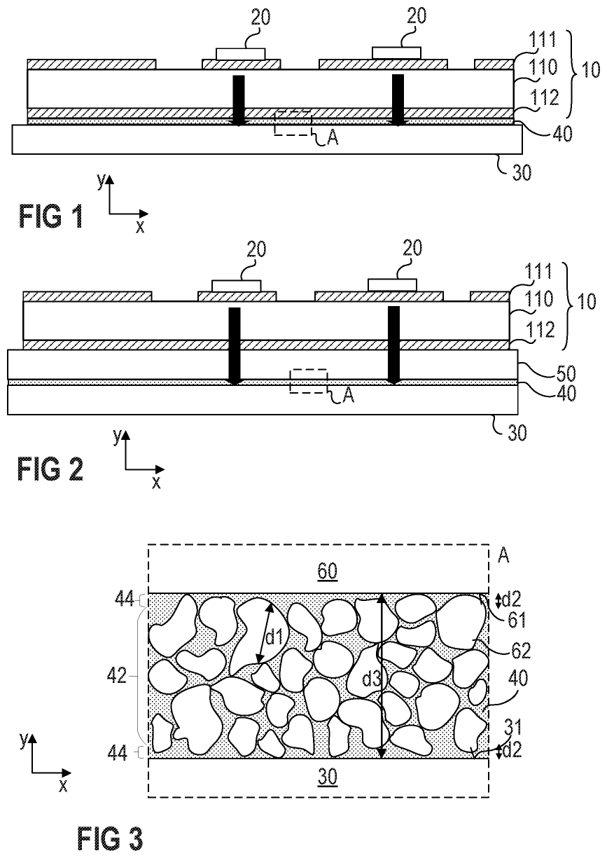

FIG. 1 exemplarily illustrates a semiconductor substrate 10. The semiconductor substrate 10 includes a dielectric insulation layer 110, a (structured) first metallization layer 111 attached to the dielectric insulation layer 110, and a second metallization layer 112 attached to the dielectric insulation layer 110. The dielectric insulation layer 110 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The semiconductor substrate 10 may be a ceramic substrate, that is, a substrate in which the dielectric insulation layer 110 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 110 may consist of or include one of the following materials: Al₂O₃, AlN, or Si₃N₄. For instance, the substrate may, e.g., be a Direct Copper Bonding (DCB) substrate, a Direct Aluminium Bonding (DAB) substrate, or an Active Metal Brazing (AMB) substrate. A substrate, however, may also be a conventional printed circuit board (PCB) or IMS (Insulated Metal Substrate) having a non-ceramic dielectric insulation layer. For instance, a non-ceramic dielectric insulation layer may consist of or include a cured resin.

Usually one or more semiconductor bodies 20 are arranged on a semiconductor substrate 10. Each of the semiconductor bodies 20 arranged on a semiconductor substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable semiconductor element. One or more semiconductor bodies 20 may form a semiconductor arrangement on the semiconductor substrate. In FIG. 1, two semiconductor bodies 20 are exemplarily illustrated. Any other number of semiconductor bodies 20, however, is also possible.

In the example illustrated in FIG. 1, the semiconductor substrate 10 is attached to a heat sink 30 with the second metallization layer 112 arranged between the dielectric insulation layer 110 and the heat sink 30. Heat that is generated by the semiconductor bodies 20 may be dissipated through the semiconductor substrate 10 to the heat sink 30. This is exemplarily illustrated by the bold arrows in FIG. 1. The second metallization layer 112 of the semiconductor substrate 10 in FIG. 1 is a continuous layer. The first metallization layer 111 is a structured layer in the arrangement illustrated in FIG. 1. “Structured layer” in this context means that the first metallization layer 111 is not a continuous layer, but includes recesses between different sections of the layer. Such recesses are schematically illustrated in FIG. 1. The first metallization layer 111 in this arrangement exemplarily includes four different sections. Different semiconductor bodies 20 may be mounted to the same or to different sections of the first metallization layer 111. Different sections of the first metallization layer 111 may have no electrical connection or may be electrically connected to one or more other sections using electrical connections such as, e.g., bonding wires. Electrical connections may also include connection plates or conductor rails, for example, to name just a few examples. The first metallization layer 111 being a structured layer, however, is only an example. It is also possible that the first metallization layer 111 is a continuous layer. According to another example, the semiconductor substrate 10 may only comprise a dielectric insulation layer 110 and a first metallization layer 111. The second metallization layer 112 may be omitted.

The power semiconductor module arrangement of FIG. 1 does not include a base plate. That is, the semiconductor substrate 10 is directly mounted on a heat sink 30. A layer of heat-conducting paste 40 is arranged between the semiconductor substrate 10 and the heat sink 30. In particular, the layer of heat-conducting paste 40 is arranged between the second metallization layer 112 and the heat sink 30. If the second metallization layer 112 is omitted, the heat-conducting paste 40 may be arranged between the dielectric insulation layer 110 and the heat sink 30.

According to another example, as is schematically illustrated in FIG. 2, the power semiconductor module arrangement may additionally include a base plate 50. The base plate 50 may be arranged between the semiconductor substrate 10 and the heat sink 30. The layer of heat-conducting material 40 in this case may be arranged between the base plate 50 and the heat sink 30.

Generally speaking, a power semiconductor module arrangement may comprise a substrate arrangement and a heat sink 30. The substrate arrangement may comprise a semiconductor substrate 10 only (FIG. 1), or may comprise a semiconductor substrate 10 arranged on a base plate 50 (FIG. 2).

The heat-conducting paste 40 that is applied between the substrate arrangement and the heat sink 30 may comprise a polymer, for example. According to one example, the heat-conducting paste 40 may comprise a silicone oil, or wax. Known heat-conducting pastes 40 generally have a thermal conductivity of between 0.5 and 1 W/mK. Other heat-conducting pastes 40 may have a thermal conductivity of up to about 3 W/mK, for example. This, however, may not be enough for certain applications. Therefore, in order to further increase the thermal conductivity of the heat-conducting paste 40, thermally conductive particles 62 may be added to the heat-conducting paste 40. This is schematically illustrated in FIG. 3, which shows a section A of the power semiconductor module arrangements of FIGS. 1 and 2. In FIG. 3, the heat-conducting paste 40 is arranged between a substrate arrangement 60 and a heat sink 30. The substrate arrangement 60 may be implemented as has been described with respect to FIGS. 1 and 2 above.

The thermally conductive particles 62 that are added to the heat-conducting paste 40 may be evenly distributed within the heat conducting paste 40. The thermal conductivity of the particles 62 is greater than the thermal conductivity of the heat-conducting paste 40. For example, the particles 62 may have a thermal conductivity of more than 7 W/mK. For example, the particles 62 may have a thermal conductivity of between 20 and 200 W/mK. The particles 62 may comprise a ceramic material, glass, or a metal powder, for example. The particles 62 may have an average maximum diameter d1 of between 2 μm and 10 μm, for example. The mixture comprising the heat-conducting paste 40 and the particles 62 has a thermal conductivity that is greater than the thermal conductivity of the heat-conductive paste 40 alone, e.g., a thermal conductivity of between 1 W/mK and 5 W/mK. The heat dissipation between the substrate arrangement 60 and the heat sink 30, therefore, is increased by adding the particles 62.

The layer of heat-conducting paste 40 between the substrate arrangement 60 and the heat sink 30, however, generally comprises three sections. A first section 42 is a section of comparably high thermal conductivity. This first section 42, however, is arranged between two sections 44 of comparably low thermal conductivity. Generally, the thermal conductivity is lower in the transition zone between the substrate arrangement 60 and the heat conductive paste 40 and in the transition zone between the heat sink 30 and the heat-conductive paste 40. In particular, heat transfer between the surfaces 61, 31 of the substrate arrangement 60 and of the heat sink 30, and the thermally conductive particles 62 is generally comparably poor. The heat transfer may be increased, when the surface roughness of the respective surfaces 61, 31 of the substrate arrangement 60 and the heat sink 30 is reduced, e.g., to less than 20 μm. A surface roughness of more than 20 μm generally does not increase the heat transfer. On the contrary, if the surface roughness significantly increases, the heat transfer may significantly deteriorate.

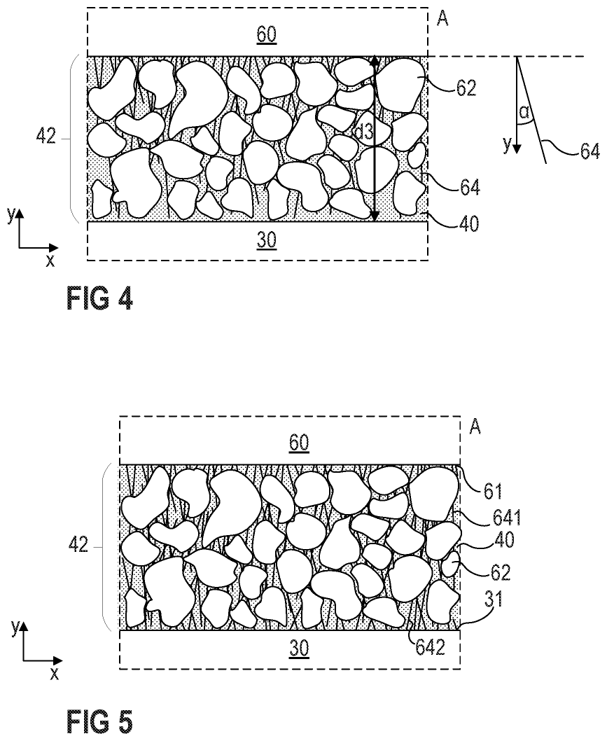

Now referring to FIG. 4, in order to increase the thermal path between at least one of the surfaces 31, 61 of the power semiconductor module arrangement and the thermally conductive particles 62, the power semiconductor arrangement further comprises a plurality of whiskers or fibers 64. The surface, e.g., may be the surface 61 of the substrate arrangement 60. As has been described with respect to FIGS. 1 and 2 above, the surface 61 may be a surface of a semiconductor substrate 10 (surface of second metallization layer 112 or of dielectric insulation layer 110) or a surface of a base plate 50. Each of the plurality of whiskers or fibers 64 has a first end and a second end, and is inseparably connected to the surface 61 with its first end. That is, each of the whiskers or fibers 64 is connected to the surface 61 with a first end and extends from the first surface 61 into the heat-conducting paste 40. The whiskers or fibers 64 may comprise a material having a high thermal conductivity. In particular, the thermal conductivity of the whiskers or fibers 64 may be higher than the thermal conductivity of the heat-conducting paste 40, i.e., in the range of the thermal conductivity of the thermally conductive particles 62. According to one example, the whiskers or fibers 64 may have a thermal conductivity of between 20 and 200 W/mK. For example, the whiskers or fibers 64 may comprise a metallic material such as Cu, Al, Cr, Mo, or Wo. According to another example, the whiskers or fibers 64 comprise graphene. Graphene is the basic structural element of many other allotropes of carbon (C), such as graphite or carbon nanotubes, for example.

Whiskers or fibers 64 comprising a metallic material generally are electrically conductive. Therefore, such whiskers or fibers 64 may provide electrically conducting channels between the substrate arrangement 61 and the heat sink 30. For some applications, however, it might be desirable not to provide an electrically conducting connection between the substrate arrangement 61 and the heat sink 30. Therefore, according to another example, the whiskers or fibers 64 may comprise an electrically insulating material such as a ceramic, for example.

Each whisker or fiber 64 may have a maximum length of between 5 μm and 50 μm. For example, each whisker or fiber 64 may have a length of between 5 μm and 20 μm. A thickness d2 of the sections of low thermal conductivity 44 (see FIG. 3) may be in the range of 1 μm, up to several μm. The whiskers or fibers 64 may be long enough to bridge such section of low thermal conductivity 44 (length of whiskers or fibers 64>d2). In particular, the whiskers or fibers 64 are configured to provide a thermal path between the surface 61 and the thermally conductive particles 62. As the whiskers or fibers 64 extend into the heat-conducting paste 40 in a vertical direction y of the power semiconductor module arrangement, they also contact one or more of the thermally conductive particles 62.

A distance d3 between the substrate arrangement 60 and the heat sink 30 in the vertical direction may be between 20 μm and 50 μm, for example. A part of the plurality of whiskers or fibers 64 may have a length that is significantly less than the distance d3 between the substrate arrangement 60 and the heat sink 30. Such whiskers or fibers 64, therefore, only bridge the short distance d2 of the section of low thermal conductivity 44. Another part of the whiskers or fibers 64, for example, may have a length that lies in the range of the distance d3 between the substrate arrangement 60 and the heat sink 30. Such whiskers or fibers 64 may extend from the surface 61 of the substrate arrangement 60 to the surface 31 of the heat sink 30 and may provide a direct thermal path between the two surfaces 31, 61. The whiskers or fibers 64 may extend parallel to the vertical direction y. This, however, is only an example. As is schematically illustrated in FIG. 4, the whiskers or fibers 64 may only essentially extend in the vertical direction such that an angle α of, e.g., 0°<α<10° results between the whiskers or fibers 64 and the vertical direction y. Different whiskers or fibers 64 may extend differently such that different angles α are formed for different whiskers or fibers 64.

In the example illustrated in FIG. 4, the whiskers or fibers 64 are inseparably connected to the first surface 61 of the substrate arrangement 60. This, however, is only an example. It is also possible that, instead, the plurality of whiskers or fibers 64 is inseparably connected to the surface 31 of the heat sink 30 (not illustrated). According to another example that is illustrated in FIG. 5, one part of the whiskers or fibers 64 may be inseparably connected to the surface 61 of the substrate arrangement 60 while another part of the whiskers or fibers 64 is inseparably connected to the surface 31 of the heat sink 30. That is, in the example of FIG. 5, whiskers or fibers 64 extend into the heat-conductive paste 40 from both surfaces 31, 61 such that the heat transfer between each of the two surfaces 31, 61 and the thermally conductive particles 62 is increased. This results in a single section 42 having a satisfactory heat conduction. Both sections of lower thermal conductivity 44 may be bridged by the whiskers or fibers 64.

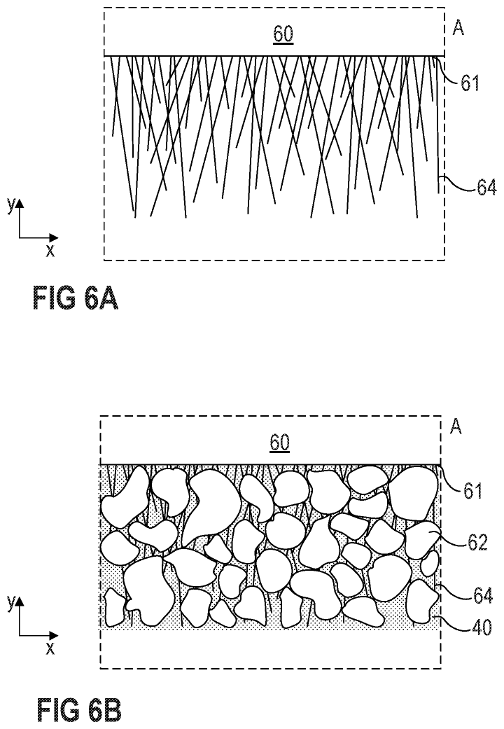

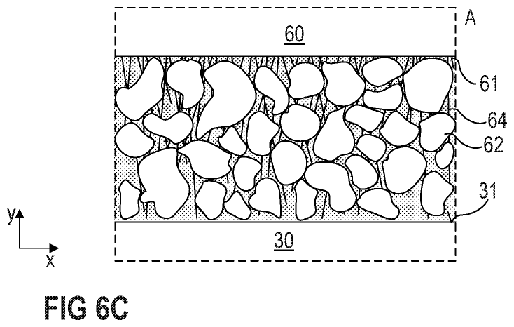

Now referring to FIGS. 6A-6C, a method for producing a substrate arrangement 60 and a power semiconductor module arrangement is exemplarily illustrated. A method for producing a substrate arrangement 60 may comprise forming a plurality of whiskers or fibers 64 on a surface 61 of the substrate arrangement 60, as is illustrated in FIG. 6A. The substrate arrangement 60 may comprise a semiconductor substrate 10 comprising a dielectric insulation layer 110, a first metallization layer 111, and (optionally) a second metallization layer 112, the surface 61 being a surface of the semiconductor substrate 10. According to another example, the substrate arrangement 60 may further comprise a base plate 50, wherein the semiconductor substrate 10 is arranged on the base plate 50, and the surface 61 is a surface of the base plate 50. Forming the plurality of whiskers or fibers 64 may comprise a galvanic growth process. For example, the material that forms the whiskers or fibers 64 may be deposited by galvanic separation. A mask may be arranged on the surface 61 of the substrate arrangement 60, the mask including microstructures such as a plurality of holes. The material may then be deposited in the microstructure, e.g., the holes. After forming the whiskers or fibers 64, the mask may be removed. Each of the whiskers or fibers 64 is inseparably connected to the surface 61 with a first end, while the second end of the whiskers or fibers 64 is a free end.

For example, a plurality of metallic whiskers or fibers 64 may be formed. For example, the whiskers or fibers 64 may comprise aluminum. After forming the metallic whiskers or fibers 64, e.g., with a galvanic growth process, the whiskers or fibers 64 may be exposed to steam. In this way, a metal oxide may be formed. If the whiskers or fibers 64 comprise aluminum, a compound may be formed by aluminum and oxygen, resulting in Al₂O₃. Other metals may be used instead of aluminum that may be transformed to a ceramic by exposing it to steam. According to another example, a nitriding process may be used, wherein nitrogen is diffused into a metal. For example, the metal whiskers or fibers 64 may be exposed to a nitrogen rich gas, e.g., NH₃, thereby forming a nitride.

The substrate arrangement 60 is often produced by a first supplier. The substrate arrangement is then sold and shipped before mounting the substrate arrangement 60 to a heat sink 30. If the same manufacturer produces the substrate arrangement 60 and mounts it to the heat sink 30, it is, however, also necessary to transport the arrangement between different manufacturing plants or production machines. The whiskers or fibers 64 are very fragile and may be easily damaged. In order to protect the micro whiskers or fibers 64 during shipping and/or handling, a heat-conducting paste 40 may be applied to the substrate arrangement 60 as is illustrated in FIG. 6B. The heat-conducting paste 40 may comprise thermally conductive particles 62. The plurality of whiskers or fibers 64 may be completely embedded in the heat-conducting paste 40. That is, the free ends of the whiskers or fibers 64 do not protrude from the heat-conducting paste 40.

A manufacturer of power semiconductor module arrangements may purchase the substrate arrangement 60 with the plurality of whiskers or fibers 64 and the heat-conducting paste 40 arranged thereon. The heat-conducting paste 40, for example, may be a heat-conducting paste that changes its phase depending on temperature. For example, at room temperature, the heat-conducting paste 40 may be solid, semi-solid, viscous or gel-like and may adhere to the surface 61. When heated, the heat-conducting paste 40 may liquefy. For example, the heat-conducting paste 40 may be applied to the substrate arrangement 60 while it is still liquid. The heat-conductive paste 40 may comprise solvents, for example. In a following step the solvents may be removed. The heat-conducting paste 40 may then form a protective layer for the whiskers or fibers 64. For example, the heat-conducting paste 40 may have a low viscosity.

If the whiskers or fibers 64 are formed on the surface 31 of the heat sink 30 instead of on the surface 61 of the substrate arrangement 60 (not illustrated), the heat-conductive paste 40 may be applied to the heat sink 30 instead of to the substrate arrangement 60. If whiskers or fibers 64 are formed on both the surface 61 of the substrate arrangement 60 and the surface 31 of the heat sink, the heat-conductive paste 40 may be applied to one of the surfaces 31, 61 only.

A method for producing a power semiconductor module may further comprise mounting the substrate arrangement 60 comprising a plurality of whiskers or fibers 64 that are embedded in a layer of heat-conductive paste 40 to a heat sink 30. This is schematically illustrated in FIG. 6C.

According to another example (not illustrated), the method for forming a power semiconductor module arrangement may alternatively or additionally comprise forming a plurality of whiskers or fibers 64 on a surface 31 of the heat sink 30, before mounting the substrate arrangement 60 to the heat sink 30.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof

What is claimed is:

1. A power semiconductor module arrangement, comprising:
a heat sink;
a substrate arrangement arranged on the heat sink in a vertical direction;
a heat-conducting paste arranged between a surface of the substrate arrangement and a surface of the heat sink in the vertical direction, wherein a plurality of thermally conducting particles is evenly distributed within the heat-conducting paste; and
a plurality of whiskers or fibers, each of the plurality of whiskers or fibers comprising a first end and a second end,
wherein the first end of each of the plurality of whiskers or fibers is inseparably connected to either the surface of the substrate arrangement or to the surface of the heat sink.

2. The power semiconductor module arrangement of claim 1, wherein each of the plurality of whiskers or fibers extends in the vertical direction through the heat-conducting paste.

3. The power semiconductor module arrangement of claim 1, wherein each of the plurality of whiskers or fibers has a length of between 5 μm and 50 μm.

4. The power semiconductor module arrangement of claim 1, wherein each of the plurality of whiskers or fibers has a length of between 5 μm and 20 μm.

5. The power semiconductor module arrangement of claim 1, wherein a distance between the substrate arrangement and the heat sink is between 20 μm and 50 μm.

6. The power semiconductor module arrangement of claim 1, wherein each of the plurality of whiskers or fibers comprises one of a metallic material, a ceramic material, and graphene.

7. The power semiconductor module arrangement of claim 6, wherein each of the plurality of whiskers or fibers comprise at least one of an oxide, a nitride, Cu, Al, Cr, Mo, Wo, and C.

8. The power semiconductor module arrangement of claim 1, wherein the substrate arrangement comprises a semiconductor substrate, and wherein the surface of the substrate arrangement is a surface of the semiconductor substrate.

9. The power semiconductor module arrangement of claim 1, wherein the substrate arrangement comprises a semiconductor substrate mounted to a base plate, and wherein the surface of the substrate arrangement is a surface of the base plate.

10. The power semiconductor module arrangement of claim 1, wherein at least a first part of the plurality of whiskers or fibers extends over a complete distance between the substrate arrangement and the heat sink such that at least the whiskers or fibers of the first part thermally contact both the substrate arrangement and the heat sink.

11. The power semiconductor module arrangement of claim 1, wherein a thermal conductivity of the plurality of whiskers or fibers is greater than a thermal conductivity of the heat conductive paste.

12. A method for producing a power semiconductor module arrangement, the method comprising:
forming a plurality of whiskers or fibers on at least one of a surface of a heat sink and a surface of a substrate arrangement;
applying a heat conducting paste to one of the surface of the substrate arrangement and the surface of the heat sink, so as to enclose the plurality of whiskers or fibers arranged on the respective surface, wherein a plurality of thermally conducting particles is evenly distributed within the heat-conducting paste; and
mounting the substrate arrangement to the heat sink with the heat conducting paste and the plurality of whiskers or fibers arranged between the surface of the substrate arrangement and the surface of the heat sink,
wherein each of the plurality of whiskers or fibers comprises a first end and a second end,
wherein the first end of each of the plurality of whiskers or fibers is inseparably connected to either the surface of the substrate arrangement or to the surface of the heat sink.

13. The method of claim 12, wherein forming the plurality of whiskers or fibers comprises a galvanic growth process.

14. The method of claim 12, wherein the heat conducting paste has a phase configured to change depending on temperature, and wherein applying the heat conducting paste comprises heating and liquefying the heat conducting paste.

15. A substrate arrangement, comprising:
a surface;
a plurality of whiskers or fibers formed on the surface; and
a heat-conducting paste enclosing the plurality of whiskers or fibers on the surface of the substrate arrangement, wherein a plurality of thermally conducting particles is evenly distributed within the heat-conducting paste,
wherein each of the plurality of whiskers or fibers comprises a first end and a second end,
wherein the first end of each of the plurality of whiskers or fibers is inseparably connected to the surface of the substrate arrangement.

16. A method for producing a substrate arrangement, the method comprising:
forming a plurality of whiskers or fibers on a surface of the substrate arrangement; and
enclosing the plurality of whiskers or fibers arranged on the surface in a heat conducting paste, wherein a plurality of thermally conducting particles is evenly distributed within the heat-conducting paste,
wherein each of the plurality of whiskers or fibers comprises a first end and a second end,
wherein the first end of each of the plurality of whiskers or fibers is inseparably connected to the surface of the substrate arrangement.

17. The method of claim 16, wherein forming the plurality of whiskers or fibers comprises a galvanic growth process.

18. The method of claim 16, wherein the heat conducting paste has a phase configured to change depending on temperature, and wherein enclosing the plurality of whiskers or fibers arranged on the surface in the heat conducting paste comprises heating and liquefying the heat conducting paste over the surface of the substrate arrangement.
